(19) United States
(12) Patent Application Publication
(10) Pub. No.: US 2010/0055815 A1
(43) Pub. Date: Mar. 4, 2010

(54) METHOD OF MANFUACTURING LENS FOR LIGHT EMITTING DIODE PACKAGE

(75) Inventors: Hyung Tae Kim, Seoul (KR); Young Ro Jeon, Gyeonggi-do (KR); Ok Ju Lee, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/246,591

(22) Filed: Oct. 7, 2008

(30) Foreign Application Priority Data
Aug. 26, 2008 (KR) 10-2008-0083164

(51) Int. Cl. H01L 21/00

(52) U.S. Cl. 438/29; 257/E21.001

(57) ABSTRACT

The present invention relates to a method of manufacturing a lens for a light emitting diode package and can reduce a manufacture cost through reduction of material loss and improve productivity through a simple process without an additional device by freely implementing a final lens shape by curing liquid resin in multi-steps.

The present invention provides a method of manufacturing a lens for a light emitting diode package including the steps of: preparing a substrate mounting a light emitting chip; forming a temporarily cured resin covering the light emitting chip on the substrate; and curing the temporarily cured resin in a lens shape.

### CROSS-REFERENCE TO RELATED APPLICATIONS

This application claims the benefit of Korean Patent Application No. 10-2008-0083164 filed with the Korea Intellectual Property Office on Aug. 26, 2008, the disclosure of which is incorporated herein by reference.

### BACKGROUND OF THE INVENTION

1. Field of the Invention

The present invention relates to a method of manufacturing a lens for a light emitting diode package; and, more particularly, to a method of manufacturing a lens for a light emitting diode package to form a lens by temporarily curing liquid resin into a gel state and curing it in a final lens shape.

2. Description of the Related Art

An LED (Light Emitting Diode) is a semiconductor device to implement multicolored light by constructing a light emitting source through a change of compound semiconductor material such as GaAs, AlGaAs, GaN and InGaInP.

Recently, an LED device in comparison with a general-purpose product with low brightness can be produced with high brightness and high quality due to rapid development of a semiconductor technology. In addition, as a blue and white LED with an excellent characteristic has been implemented, an application range of the LED has been broadened to a display, a next-generation illumination source, and so on.

A back light unit LED and an illumination LED need a lens of a light emitting unit which transmits and magnifies light and protects a light emitting chip and an electrode by functioning as packaging.

The resin used in molding the lens is thermosetting resin, for example, epoxy or silicon resin or the like. Conventional methods for molding the lens using the resin include a lens attach method, an injection molding method, a compression molding method, and so on.

The lens attach method can obtain a lens with high light transmittance by coupling the molded lens on sealing material, however, it increases a resin loss ratio and a unit cost of production.

And, the injection molding method has an advantage of reducing the resin loss ratio by molding the lens by injecting the resin into a lens-shaped mold and then curing it, however, it generates bubbles inside the resin and deteriorates mass production.

Further, the compression molding method can reduce the resin loss ratio by molding the lens by injecting the resin into a lower mold processed in a lens shape, closely adhering a substrate mounting an LED and then curing the resin, however, because a thin resin layer is formed on the substrate simultaneously and a package is large, a degree of integration is reduced, thereby deteriorating productivity.

That is, in molding the lens using the resin, there is a limit of the productivity and the yield to the conventional lens attach method and injection molding method, etc. and therefore development for a new method for molding a lens has been needed.

### SUMMARY OF THE INVENTION

The present invention has been invented in order to overcome the above-described problems and it is, therefore, an object of the present invention to provide a method of manufacturing a lens for a light emitting diode package capable of reducing a manufacture cost through reduction of material loss and improving productivity through a simple process without an additional device by freely implementing a final lens shape by curing liquid resin in multi-steps.

In accordance with one aspect of the present invention to achieve the object, there is provided a method of manufacturing a lens for a light emitting diode package including the steps of: preparing a substrate mounting a light emitting chip; forming a temporarily cured resin covering the light emitting chip on the substrate; and curing the temporarily cured resin in a lens shape.

Herein, the temporarily cured resin is formed by temporarily curing liquid resin and changing the liquid resin into a gel state.

And, the step of forming the temporarily cured resin covering the light emitting chip on the substrate includes the steps of: mounting a first mold receiving the light emitting chip inside and having a resin injection space on the substrate; injecting the liquid resin inside the first mold; forming the temporarily cured resin by temporarily curing the liquid resin; and separating the first mold from the temporarily cured resin.

Further, the first mold may be made of releasing material.

Further, the first mold may be made of Teflon resin.

Further, the liquid resin may use thermosetting resin and the thermosetting resin uses silicon resin or epoxy resin.

Further, the step of curing the temporarily cured resin in the lens shape includes the steps of: compressing a second mold processed in the lens shape on the temporarily cured resin; forming a lens by curing the temporarily cured resin; and separating the second mold from the lens.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 to FIG. 8 are cross-sectional views sequentially illustrating a method of manufacturing a lens for a light emitting diode package in accordance with an embodiment of the present invention.

### DETAILED DESCRIPTION OF THE PREFERABLE EMBODIMENTS

Hereinafter, a matter regarding to an operation effect including a technical configuration to achieve the object of a method of manufacturing a lens for a light emitting diode package in accordance with the present invention will be clearly appreciated through t he following detailed description with reference to the accompanying drawings illustrating preferable embodiment of the present invention.

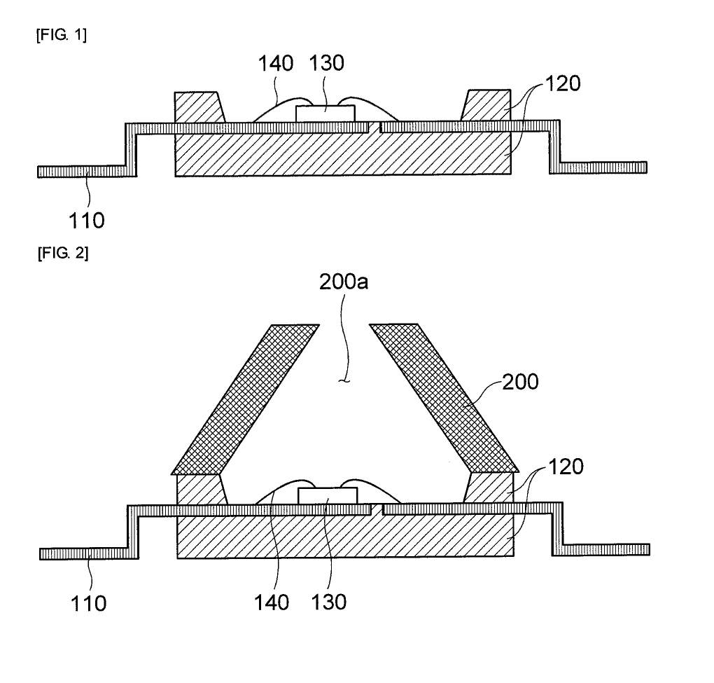

Hereinafter, a method for of manufacturing a lens for a light emitting diode package in accordance with an embodiment of the present invention will be described in detail with reference to FIG. 1 to FIG. 8.

FIG. 1 to FIG. 8 are cross-sectional views sequentially illustrating the method of manufacturing the lens for the light emitting diode package in accordance with the embodiment of the present invention.

In the method of manufacturing the lens for the light emitting diode package in accordance with the embodiment of the present invention, first of all, as shown in FIG. 1, a substrate 110 mounting a light emitting chip 130 is prepared.

The substrate 110 mounting the light emitting chip 130 may be formed in a leadframe type or the like, that is, a portion thereof is inserted and molded to be fixed in a package mold 120.

Herein, the light emitting chip 130 may use a GaN based light emitting chip or the like and may have a horizontal structure in which a P electrode and an N electrode are formed on an upper surface together or a vertical structure in which the P electrode and the N electrode are formed on the upper surface and a lower surface respectively.

When the light emitting chip 130 has the horizontal structure, as shown in FIG. 1, each electrode (not shown) provided on the upper surface of the light emitting chip 130 is electrically connected to the substrate 110 through a bonding wire 140.

The bonding wire 140 is generally made of Au.

Then, as shown in FIG. 2, a first mold 200 is mounted on the substrate 110, receives the light emitting chip 130 inside and has a resin injection space 200a. At this time, it is preferable that the first mold 200 opened at an upper part at a predetermined size to inject liquid resin 150.

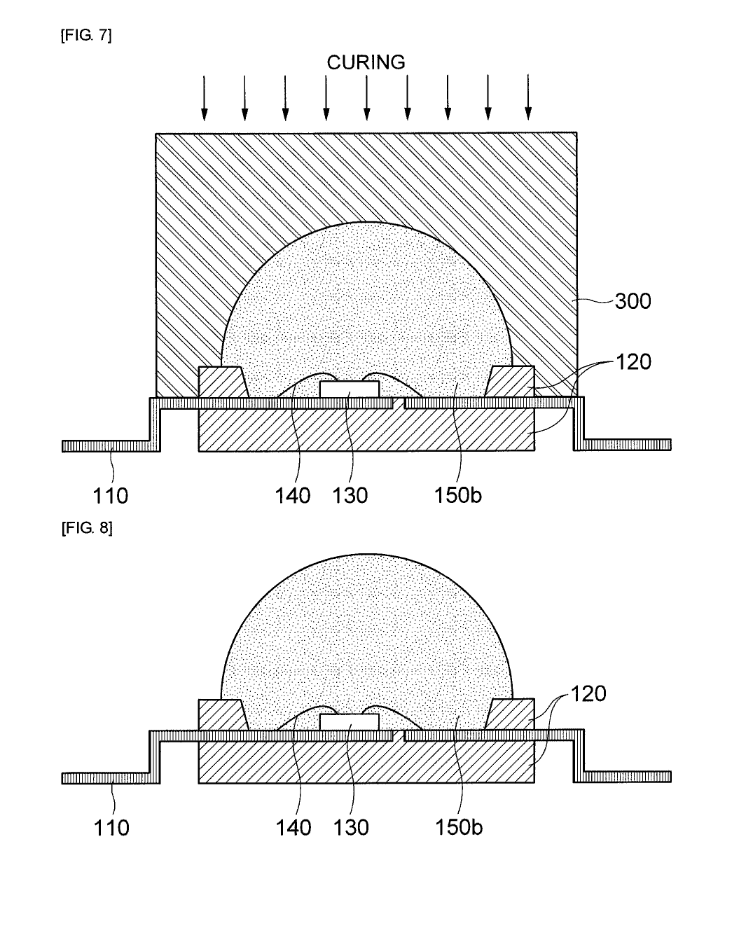

Further, it is preferable that the resin injection space 200a of the first mold 200 has the same volume as that of a lens (referring to “150b” in FIG. 7) to be finally implemented.

The first mold 200 may be made of material with a high releasing property, for example, Tefron resin.

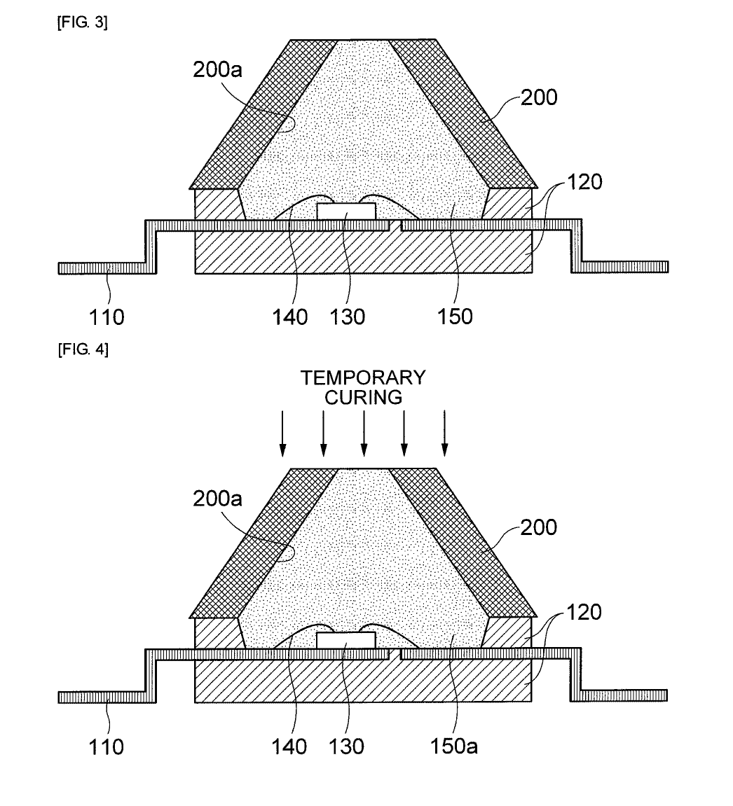

Then, as shown in FIG. 3, an inside of the first mold, that is, the resin injection space 200a is injected with the liquid resin 150 to cover the light emitting chip 130.

Herein, the liquid resin 150 may use thermosetting resin such as silicon resin, epoxy resin.

In the method of manufacturing the lens for the light emitting diode package in accordance with the embodiment of the present invention, as described above, because the liquid resin 150 is injected in the first mold having the resin injection space 200a with the same volume as that of the lens 150b, it is easy to control a quantity of the injected liquid resin 150.

Therefore, in accordance with the embodiment of the present invention, it is possible to reduce a manufacture cost of the light emitting diode package by minimizing loss of material such as the resin.

Then, as shown in FIG. 4, a temporarily cured resin 150a is formed by temporarily curing the liquid resin 150. The temporarily cured resin 150a is formed by temporarily curing the liquid resin 150 not to completely cure it and changing it into a gel state.

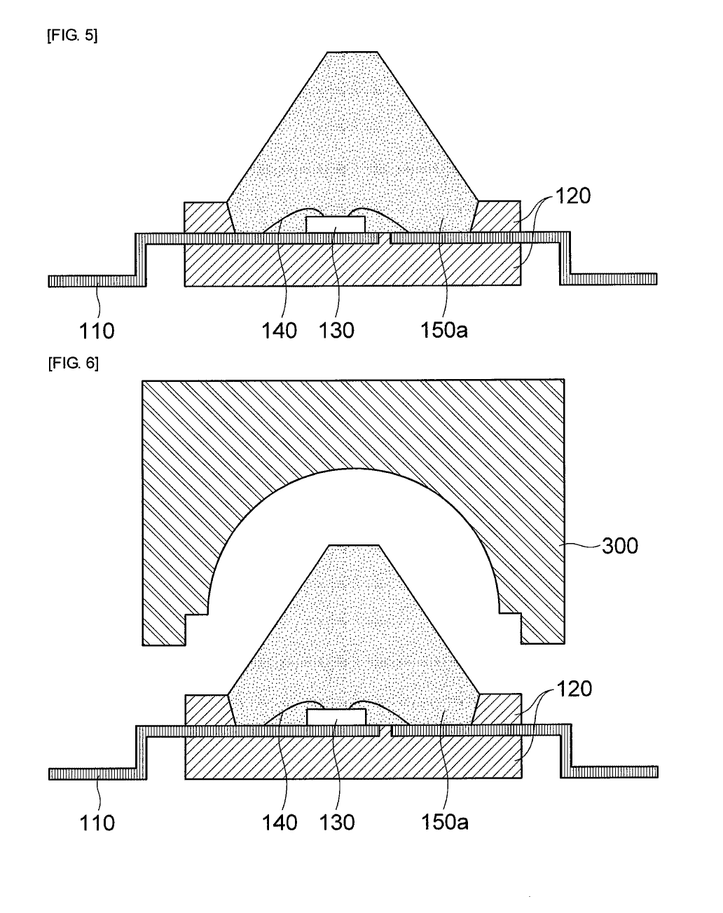

Then, as shown in FIG. 5, the first mold 200 is separated from the temporarily cured resin 150a.

As described above, the temporarily cured resin 150a changed into the gel state facilitates handling and improves the releasing property and therefore a shape thereof is not changed to be maintained intact in spite of separation of the first mold from the temporarily cured resin 150a.

Then, as shown in FIG. 6, a second mold 300 processed in a desired lens shape is prepared at an upper part of the temporarily cured resin 150a.

Then, as shown in FIG. 7, the second mold 300 is compressed on the temporarily cured resin 150a and the temporarily cured resin 150a is cured to form a lens 150b.

After completely curing the temporarily cured resin 150a in the shape of the lens 150b, as shown in FIG. 8, the second mold 300 is separated from the lens 150b.

As described above, in accordance with the embodiment of the present invention, the method of manufacturing the lens for the light emitting diode package is capable of freely implementing the lens 150b with the desired shape according to a processed shape of the second mold 300 compressed on the temporarily cured resin 150a without an additional device by injecting the liquid resin 150 into the first mold 200, temporarily curing the liquid resin 150 into a gel state, compressing the temporarily cured resin through the second mold 300 with the final lens shape and then completely curing it to form the lens 150b.

And, the method of manufacturing the lens for the light emitting diode package has an advantage of improving productive by simplifying a manufacture process by manufacturing the lens 150b with the desired shape through curing in multi-steps to adjust a curing degree of the liquid resin 150.

As described above, in accordance with the present invention, the method of manufacturing the lens for the light emitting diode package is capable of freely implementing the lens with the desired shape according to the processed shape of the second mold compressed on the temporarily cured resin without the additional device by injecting the liquid resin into the first mold, forming the temporarily cured resin in a gel state by temporarily curing the liquid resin not to completely cure it, compressing the temporarily cured resin with the second mold processed in the final lens shape and then completely curing the temporarily cured resin.

And, the present invention has advantages of reducing the manufacture cost by minimizing the material loss by facilitating the quantity control of the resin through the first mold and of improving productivity by simplifying the manufacture process by manufacturing the lens through multi-step curing of the resin.

In addition, the present invention can be applied to all types of light emitting diode packages regardless of a type of the substrate mounting the light emitting chip or the like.

As described above, although the preferable embodiment of the present invention has been shown and described, it will be appreciated by those skilled in the art that substitutions, modifications and changes may be made in this embodiment without departing from the principles and spirit of the general inventive concept, the scope of which is defined in the appended claims and their equivalents.

What is claimed is:

1. A method of manufacturing a lens for a light emitting diode package comprising the steps of:
preparing a substrate mounting a light emitting chip;
forming a temporarily cured resin covering the light emitting chip on the substrate; and
curing the temporarily cured resin in a lens shape.

2. The method of claim 1, wherein the temporarily cured resin is formed by temporarily curing liquid resin and changing the liquid resin into a gel state.

3. The method of claim 1, wherein the step of forming the temporarily cured resin covering the light emitting chip on the substrate includes the steps of:
mounting a first mold receiving the light emitting chip inside and including a resin injection space on the substrate;
injecting the liquid resin inside the first mold;
forming the temporarily cured resin by temporarily curing the liquid resin; and
separating the first mold from the temporarily cured resin.

4. The method of claim 3, wherein the first mold is made of releasing material.

5. The method of claim 4, wherein the first mold is made of Teflon resin.

6. The method of claim 3, wherein the liquid resin uses thermosetting resin.

7. The method of claim 6, wherein the thermosetting resin uses silicon resin or epoxy resin.

8. The method of claim 1, wherein the step of curing the temporarily cured resin in the lens shape includes the steps of:
compressing a second mold processed in a lens shape on the temporarily cured resin;
forming a lens by curing the temporarily cured resin; and
separating the second mold from the lens.
